(19) United States
(12) Patent Application Publication
(10) Pub. No.: US 2007/0231971 A1
(43) Pub. Date: Oct. 4, 2007

(54) Methods of Packaging Using Fluid Resin

(75) Inventor: Zhishan Peng, Shenzhen (CN)

Correspondence Address: MATTHIAS SCHOLL, 14781 MEMORIAL DRIVE, SUITE 1319, HOUSTON, TX, 77079, US

(73) Assignee: Yuejun YAN, Shenzhen (CN)

(21) Appl. No.: 11/571,526

(22) PCT Filed: Jul. 7, 2005
(86) PCT No.: PCT/CN05/00993

§ 371 Date: Jan. 2, 2007

(30) Foreign Application Priority Data
Mar. 26, 2005 (CN) 200510033878.6

(51) Int. Cl. H01L 23/28

(52) U.S. Cl. 438/127; 257/E23.116

(57) ABSTRACT

The present invention teaches fluid resin dispensing and packaging methods by which to package a bare object, such as a semiconductor chip, directly and neatly on a substrate. A peripheral boundary is lined out by solder mask on the substrate surface to be packaged so as to form a barrier to prevent the fluid resin from overflowing whereby utilizing the surface tension between the fluid resin and the outer edge of the peripheral boundary. With the aid of the fluid resin barrier, the dispensed fluid resin can be contained within the range of the design. A clean and neat resin-packaged substrate can be obtained after the resin is solidified by heating the substrate. Embodiments of the present invention are suitable for packaging of bare semiconductor chips on a variety of module substrates; the occupied area of the package is decreased; the replacement and repair of components outside of the barrier is not influenced; the cost is reduced; mass production is suitable, and the method has very wide and important applications in the production of semiconductor moduli.

### FIELD OF THE INVENTION

This invention relates to packaging methods, and more particularly, to packaging methods using fluid resin.

### DESCRIPTION OF THE RELATED ART

Many technological areas, incl. electronic communications, experience a strong demand for miniaturization and low cost manufacturing. Therefore, it is desirable to develop simple and reliable processes for the fabrication of semiconductor devices that would satisfy these demands. Specifically, in order to realize cost savings by packaging semiconductor chips in the smallest possible area on a substrate of an electronic module, it is important to control the dispensing range of the fluid resin used for packaging. If the resin flows to an undesired area, especially onto other parts or components, it will influence not only the esthetic characteristics of the substrate, the successful replacement of parts or components, and the successful repair of many expensive substrate moduli, but also the electrical characteristics of the entire substrate circuit.

### SUMMARY OF THE INVENTION

In view of the above-described problems, it is one objective of the present invention to provide methods for dispensing and packaging a fluid resin so as to package a bare object, such as a semiconductor chip, directly and neatly on a substrate.

In accordance with one objective of the present invention, provided is a method for dispensing a fluid resin and packaging therewith comprising: a substrate; a bare object(s) to be packaged on the substrate; and a metal printed circuit on the substrate, wherein the peripheral boundary of a section to be packaged on the substrate is lined out by solder mask; when a fluid resin is applied to package the bare object(s), it is dispensed to the top of the bare object until the bare object is covered totally; the fluid resin will then disperse outwardly, whereby a barrier serving to prevent the liquid resin from overflowing is formed by utilizing the surface tension between the fluid resin and the outer edges of the peripheral boundary; the gravitational force that would otherwise cause the fluid resin to overflow is kept balanced with the surface tension by controlling the quantity of the fluid resin so as to limit the dispensed fluid resin to fall within the range of the design.

As a result, the fluid resin dispensing and packaging method of the present invention is suitable for packaging of bare semiconductor chips on a variety of module substrates and is characterized by low cost, high speed, efficiency, safety and reliability, and high esthetic appeal and regularity.

Furthermore, the fluid resin dispensing and packaging method of the present invention provides the following advantages:

(1) it is suitable for resin packaging of semiconductor chips;

(2) it decreases the cost and reduces the area of the package to be occupied;

(3) the speed of the packaging is fast;

(4) it does not influence the replacement and repair of components outside of the barrier, so that the yield of the production is increased;

(5) it is suitable for mass production; and

(6) the solder-escaping metal plate(s) and the solder ink-escaping space(s) are incorporated inside of the fluid resin barrier so as to decrease the failure rate.

### BRIEF DESCRIPTION OF THE DRAWINGS

FIG. 1 is a top view of a bare object on a substrate packaged by a fluid resin in accordance with one embodiment of the present invention;

FIG. 2 is an A-A′ cross sectional view of FIG. 1; and

FIG. 3 is a top view of a bare object on a substrate prior to being packaged by fluid resin dispensing methods in accordance with one embodiment of the present invention.

### DETAILED DESCRIPTION OF THE INVENTION

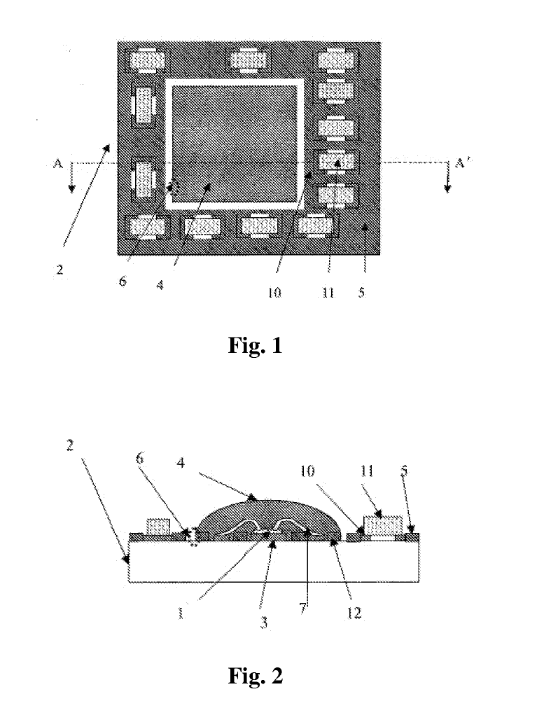

FIGS. 1 and 2 illustrate a semiconductor chip packaged in a fluid resin 4, and a plurality of electronic components outside of a resin barrier on a module substrate 2. As shown in FIG. 1, by forming a rectangular barrier 6, the range of the fluid resin 4 is limited to the resin side of the barrier 6. FIG. 2, which is an A-A′ cross-sectional view of FIG. 1, illustrates a bare object 1 encapsulated by the fluid resin 4, a metal printed circuit 3, conductive leads 7, and solder masks 5.

The peripheral boundary 12 of the section to be packaged on the substrate 2 is defined firstly by solder masks 5. When the fluid resin 4 is applied to package the bare object 1, it is dispensed to the top of the bare object 1 until the bare object 1 is fully covered. The fluid resin 4 will then flow outwardly. The barrier 6 serving to prevent the liquid resin from overflowing is formed by utilizing surface tension between the fluid resin 4 and the outer edges of the peripheral boundary 12. The gravitational force that would otherwise cause the fluid resin 4 to overflow is balanced by the surface tension, wherein the quantity of the dispensed fluid resin is controlled so as to limit the dispensed fluid resin 4 to be contained within the range of the design.

It is to be emphasized that:

a. the barrier 6 is formed by means of surface tension between the fluid resin 4 and the outer edges of the peripheral boundary 12 so as to prevent the fluid resin 4 from overflowing;

b. the term “dispensing” as used herein, quite literally, refers to the dispensing of the fluid resin 4 onto the bare object 1. The quantity of the fluid resin 4 to be dispensed needs to be controlled at just the right level, and the amount of surface tension of the fluid resin 4 needs to be considered to keep balance between the two. If the fluid resin is excessively dispensed, it will overflow to the outside of the barrier 6 and cover portions that are undesirable to be packaged, thereby, negatively influencing the replacement and repair of electronic components outside the barrier;

c. the bare object 1 can be a semiconductor chip, a conductive lead, an electrode of the bonding area, an extraction electrode, an electronic device, or a combination thereof;

d. a portion of the bare object 1 or the entire bare object 1 is connected to the metal printed circuit 3; and

e. the substrate is heated so as to solidify the fluid resin 4 after the bare object 1 is packaged within the fluid resin 4.

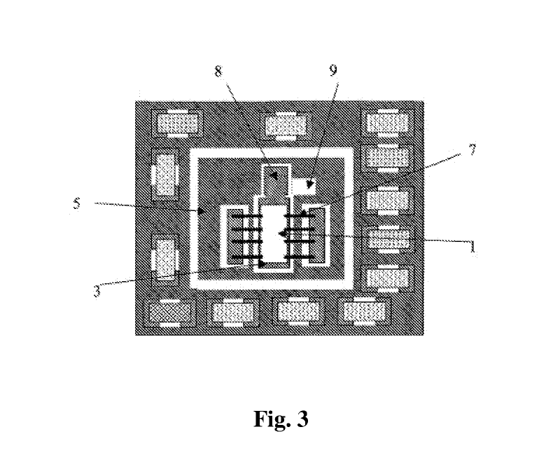

FIG. 3 illustrates a top view of a bare object disposed on a substrate prior to packaging with a fluid resin in accordance with certain embodiments of the present invention. A metal plate 8 designed to facilitate the escaping of solder and a space 9 designed to collect the escaping solder ink are enclosed within the fluid resin 4. The connection between the substrate and the bare object 1 is dependent mainly on welding. The metal plate 8 for facilitating the escaping of solder and the space 9 for collecting the escaping solder ink are disposed within the fluid resin barrier 6 on the inside so as to prevent the excess solder and solder ink from overflowing to the outside of the package resin 4 during the heating of the substrate 2, and thereby to protect the printed circuit 10 and the components 11 outside of the resin from short circuiting. By utilizing the solder-escaping metal plate 8 and the solder ink escaping space 9, the reliability of packaging by dispensing of the fluid resin is greatly enhanced. The barrier 6 has a closed, or a partially-closed and partially-open shape. It is illustrated in FIG. 1 as a closed-quadrangular shape.

What is claimed is:

1. A method for dispensing a fluid resin and for packaging therewith comprising: a substrate; a bare object to be packaged on the substrate; and a metal printed circuit on the substrate, wherein the peripheral boundary of a segment to be packaged on the substrate is defined by solder mask; when a fluid resin is applied to package the bare object, it is dispensed to the top of the bare object until the bare object is fully covered; the fluid resin will then disperse outwardly, and thereby a barrier serving to prevent the liquid resin from overflowing is formed by utilizing a surface tension between the fluid resin and the outer edges of the peripheral boundary; a gravitational force that would cause the fluid resin to overflow is kept balanced with the surface tension by controlling the quantity of the fluid resin dispensed so as to limit the dispensed fluid resin to fall within a range of the design.

2. The method for dispensing a fluid resin and for packaging therewith as claimed in claim 1, wherein said bare object is a semiconductor chip, a conductive lead, an electrode of bonding area, an extraction electrode, a resistor, an inductor, a capacitor, or a combination thereof.

3. The method for dispensing a fluid resin and for packaging therewith as claimed in claim 2, wherein the substrate is heated so as to solidify the fluid resin after said bare object is packaged within the fluid resin.

4. The method for dispensing a fluid resin and for packaging therewith as claimed in claim 3, wherein a solder escaping metal plate is disposed within the fluid resin barrier.

5. The method for dispensing a fluid resin and for packaging therewith as claimed in claim 3, wherein a solder ink escaping space is disposed within the fluid resin barrier.

6. The method for dispensing a fluid resin and for packaging therewith as claimed in claim 3, wherein said barrier has a closed-shape, or a partially-closed and partially open shape.

7. A method for packaging one or more objects, having a top, on a substrate by a fluid resin within a limit of a peripheral boundary having outer edges comprising
applying said fluid resin to said top of said object(s) until said object(s) is fully covered with said fluid resin; and
continuing to apply said fluid resin to said top of said object(s) as said fluid resin flows outwardly and forms a barrier at the outer edges of the peripheral boundary;
wherein
said barrier is formed by means of a surface tension between said fluid resin and said outer edges of said peripheral boundary;
said barrier prevents said liquid resin from flowing past said outer edges of said peripheral boundary;
said peripheral boundary is defined by a solder mask; and
a gravitational force that would otherwise cause the fluid resin to overflow is placed in equilibrium with said surface tension by controlling a quantity of said fluid resin dispensed so as to limit the quantity of said fluid resin dispensed to fall within a specified range.

8. The method of claim 7 wherein said object is a semiconductor chip, a conductive lead, an electrode, a resistor, an inductor, a capacitor or a combination thereof.

9. The method of claim 7 wherein after said fluid resin is applied, said substrate is heated so as to solidify said fluid resin.

10. The method of claim 9 wherein said substrate comprises further an escaping space disposed within said limit of said peripheral boundary, and when said substrate is heated a solder ink collects within said escaping space.

11. The method of claim 10 wherein said substrate comprises further a metal plate disposed within said limit of said peripheral boundary, and when said substrate is heated said metal plate facilitates the collection of solder within said escaping space.

12. The method of claim 7 wherein said barrier has a close shape or an open shape.
